(19) United States
(12) Patent Application Publication
(10) Pub. No.: US 2025/0151625 A1
(43) Pub. Date: May 8, 2025

(54) PIEZOELECTRIC ELEMENT, PIEZOELECTRIC CERAMIC COMPOSITION, MANUFACTURING METHOD OF PIEZOELECTRIC ELEMENT, AND MANUFACTURING METHOD OF PIEZOELECTRIC CERAMIC COMPOSITION

(71) Applicant: Murata Manufacturing Co., Ltd., Nagaokakyo-shi (JP)

(72) Inventors: Hiroyuki HAYASHI, Nagaokakyo-shi (JP); Souta ONO, Nagaokakyo-shi (JP); Yasunari MIWA, Nagaokakyo-shi (JP)

(21) Appl. No.: 19/011,826

(22) Filed: Jan. 7, 2025

Related U.S. Application Data
(63) Continuation of application No. PCT/JP2023/023608, filed on Jun. 26, 2023.

(30) Foreign Application Priority Data
Dec. 8, 2022 (JP) 2022-196465

(51) Int. Cl. H10N 30/853; C04B 35/495; C04B 35/64; C04B 37/00; C04B 41/00; C04B 41/45; C04B 41/51; C04B 41/88; H10N 30/053; H10N 30/50; H10N 30/87

(52) U.S. Cl. CPC H10N 30/8542; C04B 35/495; C04B 35/64; C04B 37/001; C04B 41/0072; C04B 41/4539; C04B 41/4578; C04B 41/5144; C04B 41/88; H10N 30/053; H10N 30/50; H10N 30/871; C04B 2235/3255; C04B 2235/3279; C04B 2235/664; C04B 2237/345; C04B 2237/68

(57) ABSTRACT

A piezoelectric element that includes a piezoelectric ceramic layer made of a ceramic sintered body having a main phase containing K, Na, Nb, and Mn, and a first secondary phase containing Mn and Nb. The piezoelectric element may further include an internal electrode layer containing Ni as a main component thereof on at least one main surface of the piezoelectric ceramic layer, and the ceramic sintered body may further have a second secondary phase containing Mn and Ni.

### CROSS REFERENCE TO RELATED APPLICATIONS

The present application is a continuation of International application No. PCT/JP2023/023608, filed Jun. 26, 2023, which claims priority to Japanese Patent Application No. 2022-196465, filed Dec. 8, 2022, the entire contents of each of which are incorporated herein by reference.

### TECHNICAL FIELD

The present description relates to a piezoelectric element, a piezoelectric ceramic composition, a manufacturing method of a piezoelectric element, and a manufacturing method of a piezoelectric ceramic composition.

### BACKGROUND ART

Conventionally, piezoelectric ceramic electronic components such as ultrasonic sensors, piezoelectric buzzers, and piezoelectric actuators have been widely known as a piezoelectric element using a piezoelectric material.

As the piezoelectric material, lead zirconate titanate (PZT)-based compounds represented by the general formula Pb(Zr, Ti)O₃ have been used so far. In recent years, as a lead-free piezoelectric material, potassium sodium niobate (KNN)-based compounds represented by the general formula (K, Na)NbO₃ have attracted attention.

Patent Document 1 discloses a piezoelectric ceramic including a polycrystal having an alkali-containing niobate perovskite structure as a main phase, in which the nickel element and the manganese element are both present at crystal grain boundaries of the polycrystal, and the content of the manganese element is 0.1 mol to 2.0 mol, the content of the nickel element is 0.1 mol to 2.0 mol, the content of the lithium element is 0.2 mol to 3.0 mol, the content of the silicon element is 0.2 mol to 3.0 mol, the content of the strontium element is 2.0 mol or less, and the content of the zirconium element is 2.0 mol or less, with respect to 100 mol of the main phase.
Patent Document 1: Japanese Patent No. 6039715

### SUMMARY OF THE DESCRIPTION

According to Patent Document 1, by intentionally unevenly distributing a nickel-containing phase together with a manganese-containing phase in the crystal grain boundaries of the main phase in a piezoelectric ceramic, it is realized to improve insulation performance while maintaining piezoelectric characteristics as a piezoelectric element.

Patent Document 1 describes that in order to produce a piezoelectric element containing a piezoelectric ceramic, a mixed powder of raw material powders as the main phase is calcined, and then fired in an air atmosphere in a state where a MnO powder and a NiO powder are mixed, that is, in a state where the calcined powder of the main phase, a Mno powder, and a NiO powder are present as independent particles.

In the example of Patent Document 1, insulation performance is evaluated by a specific resistance when a high DC electric field of 2 kV/mm is applied between external electrodes of the piezoelectric element. However, in the piezoelectric ceramic described in Patent Document 1, it has been found that when a higher electric field exceeding 2 kV/mm is applied, the specific resistance decreases in a high-temperature environment as compared with that in a room temperature environment, and it is difficult to achieve both insulation performance and piezoelectric characteristics.

The present description has been made to solve the above problems, and an object of the present description is to provide a piezoelectric element in which deterioration in insulation performance is suppressed when a high electric field is applied in a high-temperature environment. Further, an object of the present description is to provide a piezoelectric ceramic composition in which deterioration in insulation performance is suppressed when a high electric field is applied in a high-temperature environment. In addition, an object of the present description is to provide a manufacturing method of the piezoelectric element and a manufacturing method of the piezoelectric ceramic composition.

The piezoelectric element of the present description includes a piezoelectric ceramic layer made of a ceramic sintered body and having a main phase containing K, Na, Nb, and Mn, and a secondary phase containing Mn and Nb.

The piezoelectric ceramic composition of the present description is made of a ceramic sintered body having a main phase containing K, Na, Nb, and Mn, and a secondary phase containing Mn and Nb.

The manufacturing method of a piezoelectric element of the present description includes: mixing and calcining a K compound containing K, a Na compound containing Na, and a Nb compound containing Nb to prepare a calcined product; preparing a ceramic green sheet containing a Mn compound containing Mn and the calcined product; and firing the ceramic green sheet in a reducing atmosphere.

The manufacturing method of a piezoelectric ceramic composition of the present description includes: mixing and calcining a K compound containing K, a Na compound containing Na, and a Nb compound containing Nb to prepare a calcined product; preparing a molded body containing a Mn compound containing Mn and the calcined product; and firing the molded body in a reducing atmosphere.

According to the present description, it is possible to provide a piezoelectric element in which deterioration in insulation performance is suppressed when a high electric field is applied in a high-temperature environment. Furthermore, according to the present description, it is possible to provide a piezoelectric ceramic composition in which deterioration in insulation performance is suppressed when a high electric field is applied in a high-temperature environment. In addition, according to the present description, it is possible to provide a manufacturing method of the piezoelectric element and a manufacturing method of the piezoelectric ceramic composition.

### BRIEF EXPLANATION OF THE DRAWINGS

FIG. 1 is a sectional view schematically illustrating an example of a laminated piezoelectric element that is an embodiment of the piezoelectric element of the present description.

FIG. 2 is a perspective view schematically illustrating an example of a ceramic green sheet obtained in a process of manufacturing a piezoelectric actuator.

FIG. 3 is a perspective view schematically illustrating an example of a piezoelectric actuator on which external electrodes are formed.

FIG. 4 is a sectional view schematically illustrating an example of a single-plate piezoelectric element that is another embodiment of the piezoelectric element of the present description.

FIG. 5 is an example of a TEM image of a ceramic sintered body containing a main phase and a secondary phase.

FIG. 6 is a mapping image of the Mn element at the same location as in FIG. 5.

FIG. 7 is an example of an XRD pattern of a ceramic sintered body containing a main phase and a secondary phase.

FIG. 8 is an example of an XRD pattern of a ceramic sintered body obtained by firing a calcined product of a main phase containing a KNN-based compound to which Mn is added in a reducing atmosphere in order to produce a single-plate piezoelectric element.

FIG. 9 is an example of an XRD pattern of a ceramic sintered body obtained by firing a calcined product of a main phase containing a KNN-based compound to which Mn is added in a reducing atmosphere in order to produce a laminated piezoelectric element.

FIG. 10 is an example of an XRD pattern of a ceramic sintered body obtained by firing a calcined product of a main phase containing a KNN-based compound to which Mn is added in an air atmosphere in order to produce a single-plate piezoelectric element.

FIG. 11 is an XRD pattern (2θ=33° to 35°) when the addition amount of Li is changed in a laminated piezoelectric element.

FIG. 12 is an XRD pattern (2θ=41° to) 45° when the addition amount of Li is changed in a laminated piezoelectric element.

### DESCRIPTION OF THE PREFERRED EMBODIMENTS

Hereinafter, the piezoelectric element of the present description will be described. Note that the present description is not limited to the following embodiments, and may be appropriately changed without changing the gist of the present description. In addition, the present description also encompasses a combination of a plurality of individual preferable configurations described in the following embodiments.

The following drawings are schematic views, and the dimensions, the scales of aspect ratios, and the like may be different from those of actual products.

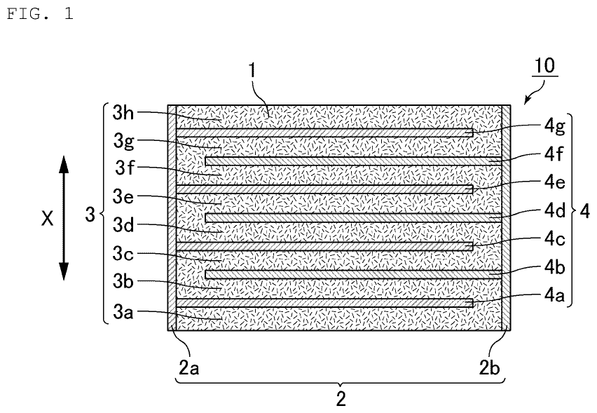

FIG. 1 is a sectional view schematically illustrating an example of a laminated piezoelectric element that is an embodiment of the piezoelectric element of the present description.

A piezoelectric actuator 10 illustrated in FIG. 1 is an example of a laminated piezoelectric element. The piezoelectric actuator 10 includes piezoelectric ceramic layers 3 (3a to 3h) and internal electrode layers 4 (4a to 4g) that are provided on at least one main surface of the piezoelectric ceramic layer 3 and contain Ni as a main component (for example, 30 wt % or more).

As shown in FIG. 1, the piezoelectric actuator 10 preferably further includes external electrodes 2 (2a and 2b) that are provided at both ends of a piezoelectric ceramic body 1 alternately including the piezoelectric ceramic layers 3 and the internal electrode layers 4. Although not shown in FIG. 1, external electrodes formed by a method such as a sputtering method may be further provided on the front surface and the back surface of the piezoelectric ceramic body 1. Examples of the conductive material constituting these external electrodes include NiCr, NiCu, Ag, Au, Pt, Ni, Cu, and Sn.

In the piezoelectric actuator 10, one end of each of the internal electrode layers 4a, 4c, 4e, and 4g is electrically connected to one external electrode 2a, and one end of each of the internal electrode layers 4b, 4d, and 4f is electrically connected to the other external electrode 2b. When a voltage is applied between the external electrode 2a and the external electrode 2b, the piezoelectric actuator 10 is displaced in an arbitrary direction due to piezoelectric effect. For example, the piezoelectric longitudinal effect makes a displacement in the longitudinal direction (stacking direction indicated by arrow X) and the piezoelectric transverse effect makes a displacement in the transverse direction (direction perpendicular to the stacking direction).

The piezoelectric ceramic layer 3 is made of a ceramic sintered body in which a main phase containing K, Na, Nb, and Mn and a secondary phase containing Mn and Nb are also present. In the ceramic sintered body constituting the piezoelectric ceramic layer 3, preferably, a secondary phase containing Mn and Ni is present. Details of each phase will be described later.

The piezoelectric actuator 10 is preferably manufactured by the following method. The present description also encompasses such a manufacturing method of a piezoelectric element.

First, as ceramic raw materials, a K compound containing K, a Na compound containing Na, and a Nb compound containing Nb are prepared, respectively. If necessary, a Li compound containing Li or the like is prepared. The form of the compound as the ceramic raw material is not particularly limited, and examples thereof include oxides, carbonates, hydrogencarbonates, and hydroxides. When a divalent element such as Ba, a tetravalent element such as Zr, or a rare earth element such as La is added, compounds for each element are prepared.

Next, a predetermined amount of the ceramic raw material is weighed, and then the weighed material is charged into a pulverizer such as a ball mill or a pot mill containing a pulverizing medium such as PSZ (partly stabilized zirconia) balls, and sufficiently wet-pulverized under a solvent such as ethanol to obtain a mixture.

In the step of preparing a mixture of the ceramic raw materials, preferably, a Mn compound containing Mn is not added.

The obtained mixture is dried and then calcined at a predetermined temperature (for example, 850° C. to 1000° C.) to synthesize a potassium sodium niobate (KNN)-based compound, and the compound is crushed to obtain a calcined product.

The obtained calcined product is added with a Mn compound such as MnCO₃. Thereafter, an organic binder and a dispersant are added, and the mixture is wet-mixed in a ball mill using pure water or an organic solvent (ethanol or the like) as a solvent to obtain a ceramic slurry. Thereafter, the ceramic slurry is molded using a doctor blade method or the like to prepare a ceramic green sheet.

Next, screen printing is performed on the ceramic green sheet using a conductive paste for an internal electrode layer containing Ni as a main component, thereby forming a conductive layer having a predetermined shape.

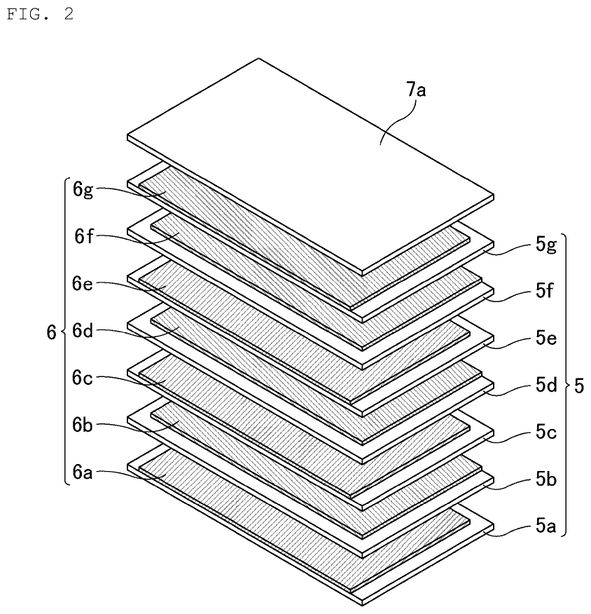

FIG. 2 is a perspective view schematically illustrating an example of a ceramic green sheet obtained in a process of manufacturing a piezoelectric actuator.

As shown in FIG. 2, ceramic green sheets 5 (5a to 5g) on which conductive layers 6 (6a to 6g) are respectively formed are stacked, and then a ceramic green sheet 7a on which the conductive layer 6 is not formed is stacked, and pressure-bonding is performed. Thus, a ceramic laminate in which the ceramic green sheets 5 and the conductive layers 6 are alternately laminated is prepared.

The obtained ceramic laminate is cut into a predetermined size, placed on a firing jig such as an alumina sagger, subjected to a debinding treatment at a predetermined temperature (for example, 250° C. to 500° C.), and then fired at a predetermined temperature (for example, 1000° C. to 1160° C.) in a reducing atmosphere to form the piezoelectric ceramic body 1 (ceramic sintered body) in which the internal electrode layers 4 are embedded.

When the conductive layer 6 containing Ni as a main component and the ceramic green sheet 5 containing a KNN-based compound as a main component are co-fired, it is necessary to perform firing in a reducing atmosphere in order to prevent oxidation of Ni. The oxygen partial pressure in the reducing atmosphere is preferably an equilibrium oxygen partial pressure at which Ni and NiO are in an equilibrium state or lower so that Ni is not oxidized.

Next, a conductive paste for an external electrode containing Ag or the like is applied to the surface of the piezoelectric ceramic body to form an external electrode.

FIG. 3 is a perspective view schematically illustrating an example of a piezoelectric actuator on which external electrodes are formed.

As shown in FIG. 3, external electrodes 2a and 2b are formed at both ends of the piezoelectric ceramic body 1 by, for example, a sputtering method or the like. Note that the external electrodes 2a and 2b only need to have good adhesion to the piezoelectric ceramic body 1, and may be formed by, for example, a thin film forming method such as a vacuum vapor deposition method, or may be formed by a method such as a baking treatment of the conductive paste.

Thereafter, a predetermined polarization treatment is performed to manufacture the piezoelectric actuator 10.

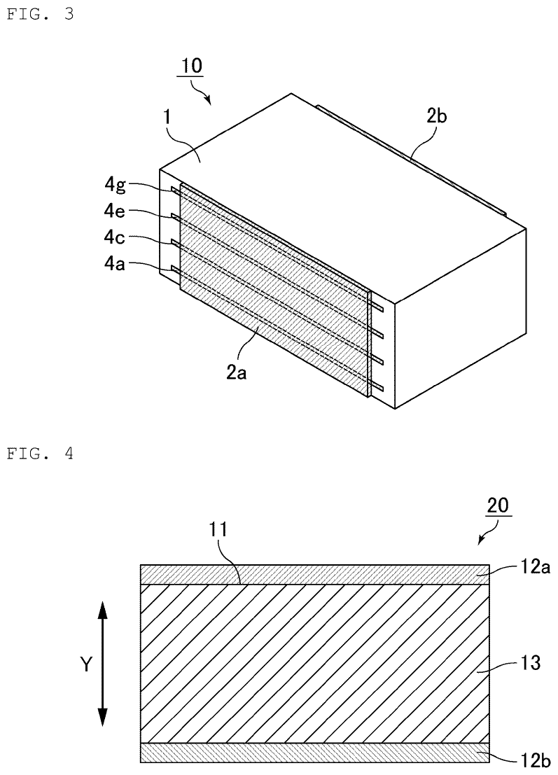

FIG. 4 is a sectional view schematically illustrating an example of a single-plate piezoelectric element that is another embodiment of the piezoelectric element of the present description.

A piezoelectric actuator 20 illustrated in FIG. 4 is an example of a single-plate piezoelectric element. The piezoelectric actuator 20 includes a piezoelectric ceramic layer 13.

As illustrated in FIG. 4, the piezoelectric actuator includes external electrodes 12a and 12b provided on the front surface and the back surface of the piezoelectric ceramic body 11 including the piezoelectric ceramic layer 13.

Examples of the conductive material constituting these external electrodes include NiCr, NiCu, Ag, Au, Pt, Ni, Cu, and Sn.

When a voltage is applied between the external electrode 12a and the external electrode 12b, the piezoelectric actuator 20 is displaced in an arbitrary direction due to piezoelectric effect. For example, the piezoelectric longitudinal effect makes a displacement in the longitudinal direction (direction indicated by arrow Y) and the piezoelectric transverse effect makes a displacement in the transverse direction (direction perpendicular to the direction indicated by arrow Y).

The piezoelectric ceramic layer 13 is made of a ceramic sintered body in which a main phase containing K, Na, Nb, and Mn and a secondary phase containing Mn and Nb are present. In the ceramic sintered body constituting the piezoelectric ceramic layer 13, a secondary phase containing Mn and Ni is optionally present. Details of each phase will be described later.

The piezoelectric actuator 20 can be prepared, for example, by preparing a molded body having a predetermined component formulation using a sheet method or press working, then applying a conductive paste for an external electrode containing Cu, Ni, Pt, or the like as a main component to both surfaces of the molded body, and co-firing the paste in a reducing atmosphere. The external electrode may be formed by a sputtering method or the like.

In the above embodiment, the laminated piezoelectric element and the single-plate piezoelectric element are exemplified, but the present description can be applied to various piezoelectric elements.

In the piezoelectric element of the present description, the piezoelectric ceramic layer is made of a ceramic sintered body in which a main phase containing K, Na, Nb, and Mn and a secondary phase containing Mn and Nb (hereinafter, referred to as first secondary phase) are present. The present description also encompasses a piezoelectric ceramic composition made of a ceramic sintered body described below.

The main phase contains a KNN-based compound. The KNN-based compound has a perovskite-type structure and is represented by the general formula (K, Na) NbO₃. The formulation of the KNN-based compound is not particularly limited.

The main phase may contain elements other than K, Na, Nb, and Mn. For example, the main phase may contain Li as an alkali metal element. The main phase may contain divalent elements such as Ba, Ca, and Sr, tetravalent elements such as Zr, Sn, and Hf, rare earth elements such as Sc, In, Yb, Y, Nd, Eu, Gd, Dy, Sm, Ho, Er, Tb, Lu, La, and Pr, Ta, Sb, and Ni.

The first secondary phase may contain elements other than Mn and Nb.

The formulation of the ceramic sintered body can be determined, for example, by performing observation using a transmission electron microscope (TEM) and energy dispersive X-ray analysis (EDX) and element distribution analysis.

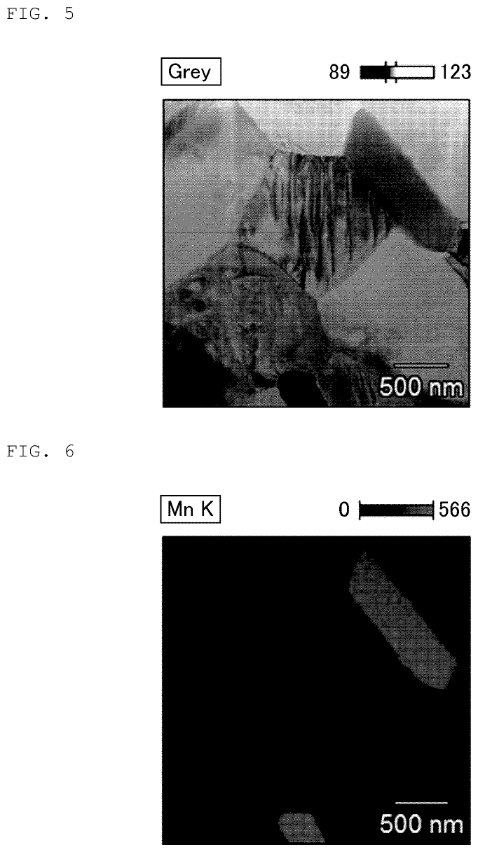

FIG. 5 is an example of a TEM image of a ceramic sintered body containing a main phase and a secondary phase. FIG. 6 is a mapping image of the Mn element at the same location as in FIG. 5.

In FIG. 6, the region where the Mn element is present corresponds to the secondary phase. As shown in FIGS. 5 and 6, the secondary phase is preferably interspersed in the main phase.

The formulation of the main phase and the secondary phase contained in the ceramic sintered body shown in FIG. 5 is shown in Table 1.

TABLE 1

| | Main | Secondary |
|---|---|---|
| | phase | phase |
| | (%) | (%) |
| K | 15.9 | 2.7 |
| Na | 21.8 | 2.7 |
| Nb | 55.9 | 42.2 |
| Ba | 2.4 | 0.0 |
| La | 0.6 | 0.0 |
| Zr | 2.9 | 2.2 |
| Mn | 0.6 | 48.0 |
| Ni | 0.0 | 2.2 |

From Table 1, the main elements constituting the main phase are K, Na, and Nb, whereas the main elements constituting the secondary phase are Mn and Nb.

In addition, the crystal structure contained in the ceramic sintered body can be analyzed by performing crystal structure analysis using X-ray diffraction (XRD).

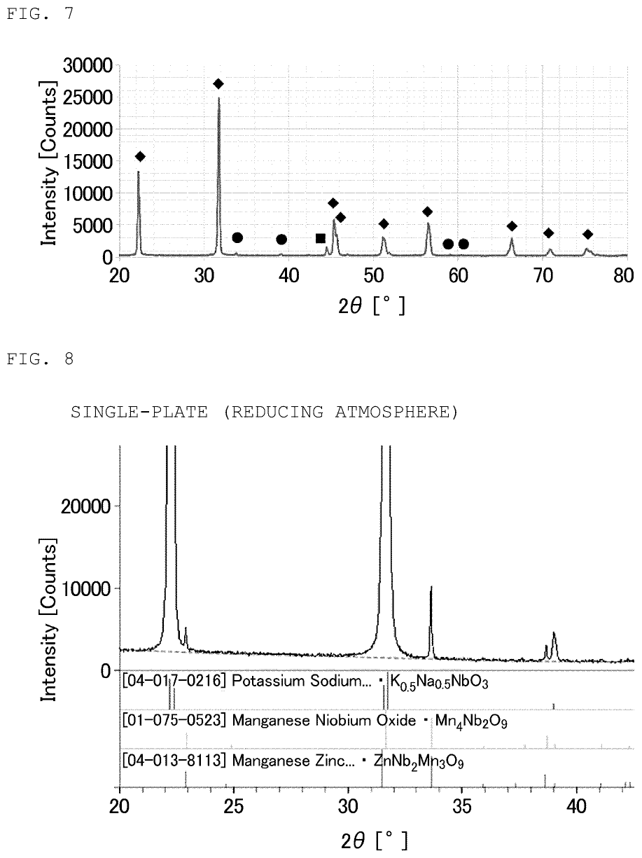

FIG. 7 is an example of an XRD pattern of a ceramic sintered body containing a main phase and a secondary phase.

In FIG. 7, in addition to the peaks marked with and derived from the main phase containing the KNN-based compound and the peak marked with ▪ and derived from Ni, the peaks marked with ● and derived from the secondary phase containing Mn and Nb can be observed. In the example shown in FIG. 7, the secondary phase containing Mn and Nb has a Mn₄Nb₂O₉ type crystal structure.

The above results suggest that the Mn, which is added after synthesizing the main phase containing the KNN-based compound by calcining, pulls out Nb from the B site during firing. When Nb incorporated into the crystal during calcination is taken into the secondary phase (heterogeneous phase) containing Mn during firing and goes out of the crystal, Nb defects having an acceptor function are generated in the B site in the main phase. One mole of the Nb defect contributes to charge compensation for 2.5 mol of oxygen defects, which is considered to lead to improved insulation performance in a high-temperature environment. A part of Nb in the B site may be substituted with an element such as Zr, and in this case, the element such as Zr may be incorporated into the secondary phase (heterogeneous phase) containing Mn and go out of the crystal.

In addition, K and Na (or Li) solid-solved in the A site in the crystal of the main phase may also be taken into the secondary phase (heterogeneous phase) containing Mn and go out of the crystal to form K defects and Na defects (or Li defects) in the A site. Since these defects also provides an acceptor function, it is considered that both of them contribute to charge compensation for oxygen defects, leading to improved insulation performance in a high-temperature environment.

As described above, in the present description, it is considered that the elements contained in the main phase are contained in the secondary phase, thereby forming defects in the main phase and improving the insulation performance in a high-temperature environment.

FIG. 8 is an example of an XRD pattern of a ceramic sintered body obtained by firing a calcined product of a main phase containing a KNN-based compound to which Mn is added in a reducing atmosphere in order to produce a single-plate piezoelectric element.

As shown in FIG. 8, the secondary phase containing Mn and Nb preferably has a peak in a range of 2θ=33° to 35° in crystal structure analysis using X-ray diffraction. In the example shown in FIG. 8, the secondary phase containing Mn and Nb has a Mn₄Nb₂O₉ type crystal structure.

Preferably, in the crystal structure analysis using X-ray diffraction, the main phase has a maximum peak intensity I₀, and the secondary phase containing Mn and Nb has a maximum peak intensity I₁ in a range of 2θ=33° to 35°, and a maximum peak intensity ratio represented by I₁/I₀ is more than 0.019 and less than 0.070.

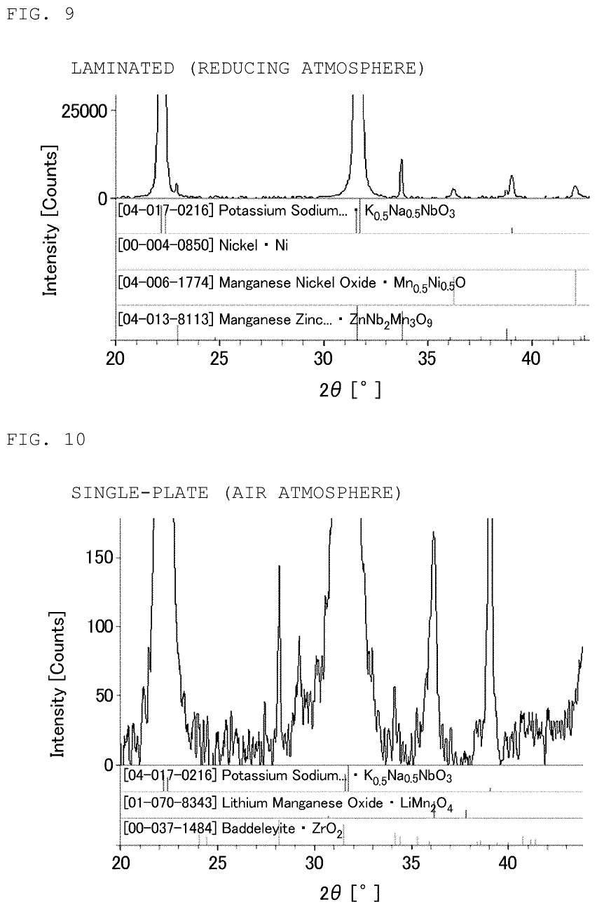

FIG. 9 is an example of an XRD pattern of a ceramic sintered body obtained by firing a calcined product of a main phase containing a KNN-based compound to which Mn is added in a reducing atmosphere in order to produce a laminated piezoelectric element.

In the laminated piezoelectric element, an internal electrode layer containing Ni as a main component is provided on at least one main surface of the piezoelectric ceramic layer. In this case, as shown in FIG. 9, the secondary phase containing Mn and Nb preferably has a peak in a range of 2θ=33° to 35° in crystal structure analysis using X-ray diffraction. In the example shown in FIG. 9, the secondary phase containing Mn and Nb has a ZnNb₂Mn₃O₉ type crystal structure.

When the internal electrode layer containing Ni as a main component is provided on at least one main surface of the piezoelectric ceramic layer, preferably, a secondary phase containing Mn and Ni (hereinafter, also referred to as second secondary phase) is also present in the ceramic sintered body.

The second secondary phase may contain elements other than Mn and Ni.

As shown in FIG. 9, the secondary phase containing Mn and Ni preferably has a peak in a range of 2θ=41° to 44° in crystal structure analysis using X-ray diffraction. In the example shown in FIG. 9, the secondary phase containing Mn and Ni has a Mn_{0.5}Ni_{0.5}O (that is, MnNiO₂) type crystal structure.

Preferably, in the crystal structure analysis using X-ray diffraction, the main phase has a maximum peak intensity I₀, and the secondary phase containing Mn and Ni has a maximum peak intensity I₂ in a range of 2θ=41° to 44°, and a maximum peak intensity ratio represented by I₂/I₀ is more than 0 and less than 0.04.

As shown in FIGS. 8 and 9, the ceramic sintered body preferably has no peak around 2θ=29° in crystal structure analysis using X-ray diffraction.

FIG. 10 is an example of an XRD pattern of a ceramic sintered body obtained by firing a calcined product of a main phase containing a KNN-based compound to which Mn is added in an air atmosphere in order to produce a single-plate piezoelectric element.

In the example shown in FIG. 10 in which firing was performed in an air atmosphere, unlike the example shown in FIG. 8 in which firing was performed in a reducing atmosphere, it can be confirmed that a secondary phase having a peak in a range of 2θ=33° to 35° is not formed in crystal structure analysis using X-ray diffraction. Instead, the peaks of LiMn₂O₄ and Zro₂ can be observed. The peak around 2θ=34° is the peak of Zro₂, and is different from the peak of the secondary phase containing Mn and Nb.

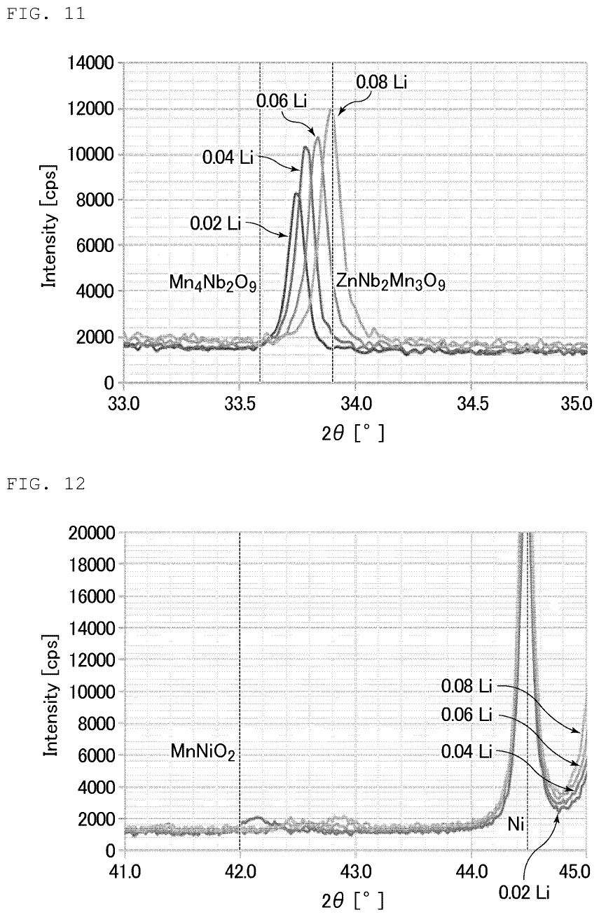

FIG. 11 is an XRD pattern (2θ=33° to) 35° when the addition amount of Li is changed in a laminated piezoelectric element.

As shown in FIG. 11, in the range of 2θ=33° to 35°, peaks having a Mn₄Nb₂O₉ type or ZnNb₂Mn₃O₉ type crystal structure can be observed as the secondary phase containing Mn and Nb.

FIG. 12 is an XRD pattern (2θ=41° to) 45° when the addition amount of Li is changed in a laminated piezoelectric element.

As shown in FIG. 12, in the range of 2θ=41° to 44°, peaks having a MnNiO₂ type crystal structure can be observed as the secondary phase containing Mn and Ni.

The following content is disclosed in the present specification.

<1> A piezoelectric element including a piezoelectric ceramic layer made of a ceramic sintered body having a main phase containing K, Na, Nb, and Mn, and a first secondary phase containing Mn and Nb.

<2> The piezoelectric element according to <1>, wherein the first secondary phase containing Mn and Nb has a peak in a range of 2θ=33° to 35° in crystal structure analysis using X-ray diffraction.

<3> The piezoelectric element according to <2>, wherein, in the crystal structure analysis using X-ray diffraction, the main phase has a maximum peak intensity I₀, and the first secondary phase containing Mn and Nb has a maximum peak intensity I₁ in a range of 2θ=33° to 35°, and a maximum peak intensity ratio represented by I₁/I₀ is more than 0.019 and less than 0.070.

<4> The piezoelectric element according to any one of <1> to <3>, further including an internal electrode layer on at least one main surface of the piezoelectric ceramic layer and which contains Ni as a main component thereof.

<5> The piezoelectric element according to <4>, wherein the ceramic sintered body further has a second secondary phase containing Mn and Ni.

<6> The piezoelectric element according to <5>, wherein, in a crystal structure analysis using X-ray diffraction, the second secondary phase containing Mn and Ni has a peak in a range of 2θ=41° to 44°.

<7> The piezoelectric element according to <6>, wherein, in the crystal structure analysis using X-ray diffraction, the main phase has a maximum peak intensity I₀, and the second secondary phase containing Mn and Ni has a maximum peak intensity I₂ in a range of 2θ=41° to 44°, and a maximum peak intensity ratio represented by I₂/I₀ is more than 0 and less than 0.04.

<8> A piezoelectric ceramic composition including a ceramic sintered body having a main phase containing K, Na, Nb, and Mn, and a first secondary phase containing Mn and Nb.

<9> The piezoelectric ceramic composition according to <8>, wherein the first secondary phase containing Mn and Nb has a peak in a range of 2θ=33° to 35° in crystal structure analysis using X-ray diffraction.

<10> The piezoelectric ceramic composition according to <9>, wherein, in the crystal structure analysis using X-ray diffraction, the main phase has a maximum peak intensity I₀, and the first secondary phase containing Mn and Nb has a maximum peak intensity I₁ in a range of 2θ=33° to 35°, and a maximum peak intensity ratio represented by I₁/I₀ is more than 0.019 and less than 0.070.

<11> The piezoelectric ceramic composition according to any one of <8> to <10>, wherein the ceramic sintered body has a second secondary phase containing Mn and Ni.

<12> The piezoelectric ceramic composition according to <11>, wherein, in a crystal structure analysis using X-ray diffraction, the second secondary phase containing Mn and Ni has a peak in a range of 2θ=41° to 44°.

<13> The piezoelectric ceramic composition according to <12>, wherein, in the crystal structure analysis using X-ray diffraction, the main phase has a maximum peak intensity I₀, and the second secondary phase containing Mn and Ni has a maximum peak intensity I₂ in a range of 2θ=41° to 44°, and a maximum peak intensity ratio represented by I₂/I₀ is less than 0.04.

<14> A method of manufacturing a piezoelectric element, the method including: mixing and calcining a K compound containing K, a Na compound containing Na, and a Nb compound containing Nb to prepare a calcined product; preparing a ceramic green sheet containing a Mn compound containing Mn and the calcined product; and firing the ceramic green sheet in a reducing atmosphere.

<15> The method of manufacturing a piezoelectric element according to <14>, the method further including forming a conductive layer on the ceramic green sheet using a conductive paste containing Ni as a main component before the firing of the ceramic green sheet.

<16> The method of manufacturing a piezoelectric element according to <15>, the method further including laminating the ceramic green sheet on which the conductive layer has been formed to prepare a ceramic laminate before the firing of the ceramic green sheet.

<17> A method of manufacturing a piezoelectric ceramic composition, the method including: mixing and calcining a K compound containing K, a Na compound containing Na, and a Nb compound containing Nb to prepare a calcined product; preparing a molded body containing a Mn compound containing Mn and the calcined product; and firing the molded body in a reducing atmosphere.

### EXAMPLES

Hereinafter, Examples in which the piezoelectric element of the present description is more specifically disclosed will be described. Note that the present description is not limited only to these Examples.

### Example 1-1

In Example 1-1, laminated piezoelectric elements different in Mn addition amount were prepared as shown in Table 2.

First, as ceramic raw materials, K₂CO₃, Na₂CO₃, Li₂CO₃, Nb₂O₃, and BaZrO₃ were prepared. The ceramic raw material was weighed in a predetermined amount, and then the weighed material was put into a ball mill and sufficiently wet-pulverized to obtain a mixture. The obtained mixture was dried, and then calcined and crushed to obtain a calcined product.

Next, the calcined product and MnCO₃ were prepared, weighed in a predetermined amount, charged into a ball mill together with an organic binder, a dispersant, and a solvent (pure water or an organic solvent (ethanol or the like)), and sufficiently wet-mixed. Thereafter, the resultant was molded using a doctor blade method to obtain a ceramic green sheet.

Next, a conductive paste for an internal electrode layer containing Ni as a main component was used to form a conductive layer having a predetermined pattern on the ceramic green sheet by screen printing. A predetermined number of the ceramic green sheets on which the conductive layer was formed were laminated, and then a ceramic green sheet on which the conductive layer was not formed was laminated and pressure-bonding was performed. Thus, a ceramic laminate was prepared.

The ceramic laminate was fired in a reducing atmosphere adjusted to be on the 0.5 digit reduction side from the equilibrium oxygen partial pressure at which Ni and Nio were in an equilibrium state, thereby preparing a piezoelectric ceramic body (ceramic sintered body) including an internal electrode layer mainly composed of Ni.

Sputtering treatment was performed on both main surfaces of the obtained piezoelectric ceramic body to form an external electrode made of Ag. Thereafter, an electric field of 3 kV/mm was applied for 3 minutes in air at room temperature to perform polarization treatment. Thus, samples with sample numbers 1 to 7 were prepared.

### Example 1-2

In Example 1-2, laminated piezoelectric elements different in Mn addition amount were prepared as shown in Table 3. A piezoelectric element was prepared by the same method as in Example 1-1 except that the ceramic laminate was fired in a reducing atmosphere adjusted to be on the 1 digit reduction side from the equilibrium oxygen partial pressure. Thus, samples with sample numbers 8 to 14 were prepared.

### Example 2-1

In Example 2-1, the Mn addition amount was fixed to 5 mol % as shown in Table 4, and laminated piezoelectric elements different in NiO addition amount were prepared. In the same manner as in Example 1-1, a ceramic laminate was fired in a reducing atmosphere adjusted to be on the 0.5 digit reduction side from the equilibrium oxygen partial pressure to prepare a piezoelectric element. Thus, sample numbers 15 to 22 were prepared.

### Example 2-2

In Example 2-2, the Mn addition amount was fixed to 5 mol % as shown in Table 5, and laminated piezoelectric elements different in NiO addition amount were prepared. A piezoelectric element was prepared by the same method as in Example 2-1 except that the ceramic laminate was fired in a reducing atmosphere adjusted to be on the 1 digit reduction side from the equilibrium oxygen partial pressure. Thus, samples with sample numbers 23 to 30 were prepared.

For each of the samples with sample numbers 1 to 30, the crystal structure contained in the ceramic sintered body was analyzed by performing crystal structure analysis using X-ray diffraction.

As a result, in the samples 1 and 8, to which Mn was not added, it was confirmed that the main phase containing the KNN-based compound was present in the ceramic sintered body. On the other hand, in the samples 2 to 7 and 9 to 30, to which Mn was added, it was confirmed that the main phase containing the KNN-based compound, the secondary phase containing Mn and Nb, and the secondary phase containing Mn and Ni were present in the ceramic sintered body.

In the crystal structure analysis using X-ray diffraction for each of the samples with sample numbers 1 to 30, the main phase has a maximum peak intensity I₀, and the secondary phase containing Mn and Nb has a maximum peak intensity I₁ in a range of 2θ=33° to 35°, and the secondary phase containing Mn and Ni has a maximum peak intensity I₂ in a range of 2θ=41° to 44°. Tables 2 to 5 shows a maximum peak intensity ratio represented by I₁/I₀ and a maximum peak intensity ratio represented by I₂/I₀. As described above, since the peak of the secondary phase containing Mn and Nb and the peak of the secondary phase containing Mn and Ni could not be detected in the samples 1 and 8, the maximum peak intensity ratio is indicated by “-”.

For each of the samples with sample numbers 1 to 30, the insulation performance was evaluated by measuring the specific resistance ρ (Ω·m) when a direct electric field of 3 kV/mm was applied at room temperature (25° C.), 85° C., or 125° C. The values of log p of each sample are shown in Tables 2 to 5.

Piezoelectric characteristics of each of the samples with sample numbers 1 to 30 were evaluated by measuring the piezoelectric constant d₃₁ (pC/N). The piezoelectric constant d₃₁ was calculated from the relative permittivity ε₃₃ measured with an impedance analyzer and the electromechanical coupling coefficient k. The values of the piezoelectric constant d₃₁ of each sample are shown in Tables 2 to 5.

TABLE 2
Example 1-1 (0.5 digit reduction side)

| | Mn | Peak | Peak | Log ρ[ρ: Ω · m] | | | |
|---|---|---|---|---|---|---|---|
| | addition | intensity | intensity | Room | | | |
| Sample | amount | ratio | ratio | temper- | | | d₃₁ |
| number | [mol %] | I₁/I₀ | I₂/I₀ | ature | 85° C. | 125° C. | [pC/N] |
| *1 | 0 | — | — | 8.2 | 6.3 | 5.2 | 55 |
| 2 | 1 | 0.016 | 0.006 | 8.9 | 7.1 | 5.9 | 54 |
| 3 | 2 | 0.019 | 0.011 | 9.4 | 8.0 | 6.9 | 53 |
| 4 | 3 | 0.021 | 0.012 | 10.4 | 8.7 | 7.5 | 51 |
| 5 | 5 | 0.031 | 0.016 | 11.5 | 10.4 | 9.2 | 49 |
| 6 | 10 | 0.051 | 0.027 | 11.7 | 10.4 | 9.3 | 42 |
| 7 | 15 | 0.070 | 0.041 | 12.0 | 10.7 | 9.8 | 35 |

TABLE 3
Example 1-2 (1 digit reduction side)

| | Mn | Peak | Peak | Log ρ[ρ: Ω · m] | | | |
|---|---|---|---|---|---|---|---|
| | addition | intensity | intensity | Room | | | |
| Sample | amount | ratio | ratio | temper- | | | d₃₁ |
| number | [mol %] | I₁/I₀ | I₂/I₀ | ature | 85° C. | 125° C. | [pC/N] |
| *8 | 0 | — | — | 9.1 | 6.7 | 5.5 | 67 |
| 9 | 1 | 0.011 | 0.003 | 9.8 | 7.6 | 6.2 | 66 |
| 10 | 2 | 0.014 | 0.005 | 10.4 | 8.5 | 7.2 | 65 |
| 11 | 3 | 0.015 | 0.005 | 11.5 | 9.3 | 7.9 | 62 |
| 12 | 5 | 0.022 | 0.007 | 12.7 | 11.1 | 9.7 | 60 |
| 13 | 10 | 0.036 | 0.012 | 13.0 | 11.1 | 9.8 | 51 |
| 14 | 15 | 0.050 | 0.018 | 13.2 | 11.5 | 10.3 | 43 |

TABLE 4
Example 2-1 (0.5 digit reduction side)

| | Mn | NiO | Peak | Peak | | | | |
|---|---|---|---|---|---|---|---|---|
| | addition | addition | intensity | intensity | Log ρ[ρ: Ω · m] | | | |
| Sample | amount | amount | ratio | ratio | Room | | | d₃₁ |
| number | [mol %] | [mol %] | I₁/I₀ | I₂/I₀ | temperature | 85° C. | 125° C. | [pC/N] |
| 15 | 5 | 0 | 0.031 | 0.016 | 11.5 | 10.4 | 9.2 | 49 |
| 16 | 5 | 1 | 0.030 | 0.016 | 12.1 | 10.5 | 9.3 | 48 |
| 17 | 5 | 2 | 0.026 | 0.018 | 12.1 | 10.5 | 9.3 | 47 |
| 18 | 5 | 3 | 0.025 | 0.024 | 12.1 | 10.5 | 9.3 | 47 |
| 19 | 5 | 5 | 0.024 | 0.028 | 11.9 | 9.9 | 8.7 | 45 |
| 20 | 5 | 7 | 0.022 | 0.033 | 11.8 | 9.6 | 8.2 | 43 |
| 21 | 5 | 10 | 0.021 | 0.039 | 11.6 | 9.1 | 7.4 | 41 |
| 22 | 5 | 15 | 0.016 | 0.054 | 11.3 | 8.2 | 5.9 | 37 |

TABLE 5
Example 2-2 (1 digit reduction side)

| | Mn | NiO | Peak | Peak | | | | |
|---|---|---|---|---|---|---|---|---|
| | addition | addition | intensity | intensity | Log ρ[ρ: Ω · m] | | | |
| Sample | amount | amount | ratio | ratio | Room | | | d₃₁ |
| number | [mol %] | [mol %] | I₁/I₀ | I₂/I₀ | temperature | 85° C. | 125° C. | [pc/N] |
| 23 | 5 | 0 | 0.022 | 0.007 | 12.7 | 11.1 | 9.7 | 60 |
| 24 | 5 | 1 | 0.021 | 0.007 | 13.4 | 11.3 | 9.8 | 59 |
| 25 | 5 | 2 | 0.019 | 0.008 | 13.4 | 11.2 | 9.7 | 58 |
| 26 | 5 | 3 | 0.018 | 0.011 | 13.4 | 11.2 | 9.8 | 57 |
| 27 | 5 | 5 | 0.017 | 0.012 | 13.1 | 10.9 | 9.6 | 55 |
| 28 | 5 | 7 | 0.016 | 0.015 | 13.0 | 10.6 | 9.0 | 53 |
| 29 | 5 | 10 | 0.015 | 0.017 | 12.9 | 10.1 | 8.2 | 50 |
| 30 | 5 | 15 | 0.011 | 0.024 | 12.5 | 9.2 | 6.6 | 45 |

In Tables 2 to 5, samples marked with * are Comparative Examples, which are outside the scope of the present description.

From the results in Tables 2 to 5, it is considered that the secondary phase containing Mn and Nb is formed in the ceramic sintered body by firing the fired product of the main phase containing the KNN-based compound to which Mn is added in a reducing atmosphere. Furthermore, it is considered that the secondary phase containing Mn and Ni is also formed in the ceramic sintered body by co-firing with the conductive layer (internal electrode layer) containing Ni as a main component.

From Table 2, in samples 4 to 6, in which the maximum peak intensity ratio represented by I₁/I₀ is more than 0.019 and less than 0.070, the specific resistance log ρ at 85° C. is larger than 8.5, the specific resistance log ρ at 125° C. is larger than 7, and therefore sufficient insulation performance is exhibited. In samples 2 to 6, in which the maximum peak intensity ratio represented by I₂/I₀ is more than 0 and less than 0.04, the piezoelectric constant d₃₁ is more than 40 pC/N, and therefore the piezoelectric characteristics are excellent. The same applies to Tables 3 to 5.

### DESCRIPTION OF REFERENCE SYMBOLS

1, 11: Piezoelectric ceramic body
2, 2a, 2b, 12a, 12b: External electrode
3, 3a to 3h, 13: Piezoelectric ceramic layer
4, 4a to 4g: Internal electrode layer
5, 5a to 5g, 7a: Ceramic green sheet
6, 6a to 6g: Conductive layer
10, 20: Piezoelectric actuator (piezoelectric element)

1. A piezoelectric element comprising:
a piezoelectric ceramic layer made of a ceramic sintered body having a main phase containing K, Na, Nb, and Mn, and a first secondary phase containing Mn and Nb.

2. The piezoelectric element according to claim 1, wherein the first secondary phase containing Mn and Nb has a peak in a range of 2θ=33° to 35° in a crystal structure analysis using X-ray diffraction.

3. The piezoelectric element according to claim 1, wherein, in a crystal structure analysis using X-ray diffraction, the main phase has a maximum peak intensity I₀, and the first secondary phase containing Mn and Nb has a maximum peak intensity I₁ in a range of 2θ=33° to 35°, and a maximum peak intensity ratio represented by I₁/I₀ is more than 0.019 and less than 0.070.

4. The piezoelectric element according to claim 1, further comprising an internal electrode layer on at least one main surface of the piezoelectric ceramic layer, the internal electrode layer containing Ni as a main component.

5. The piezoelectric element according to claim 4, wherein the ceramic sintered body further has a second secondary phase containing Mn and Ni.

6. The piezoelectric element according to claim 5, wherein, in a crystal structure analysis using X-ray diffraction, the second secondary phase containing Mn and Ni has a peak in a range of 2θ=41° to 44°.

7. The piezoelectric element according to claim 5, wherein the first secondary phase containing Mn and Nb has a peak in a range of 2θ=33° to 35° in the crystal structure analysis using X-ray diffraction.

8. The piezoelectric element according to claim 5, wherein, in a crystal structure analysis using X-ray diffraction, the main phase has a maximum peak intensity I₀, and the second secondary phase containing Mn and Ni has a maximum peak intensity I₂ in a range of 2θ=41° to 44°, and a maximum peak intensity ratio represented by I₂/I₀ is more than 0 and less than 0.04.

9. The piezoelectric element according to claim 8, wherein, in the crystal structure analysis using X-ray diffraction, the first secondary phase containing Mn and Nb has a maximum peak intensity I₁ in a range of 2θ=33° to 35°, and a maximum peak intensity ratio represented by I₁/I₀ is more than 0.019 and less than 0.070.

10. A piezoelectric ceramic composition comprising a ceramic sintered body having a main phase containing K, Na, Nb, and Mn, and a first secondary phase containing Mn and Nb.

11. The piezoelectric ceramic composition according to claim 10, wherein the first secondary phase containing Mn and Nb has a peak in a range of 2θ=33° to 35° in a crystal structure analysis using X-ray diffraction.

12. The piezoelectric ceramic composition according to claim 10, wherein, in a crystal structure analysis using X-ray diffraction, the main phase has a maximum peak intensity I₀, and the first secondary phase containing Mn and Nb has a maximum peak intensity I₁ in a range of 2θ=33° to 35°, and a maximum peak intensity ratio represented by I₁/I₀ is more than 0.019 and less than 0.070.

13. The piezoelectric ceramic composition according to claim 10, wherein the ceramic sintered body has a second secondary phase containing Mn and Ni.

14. The piezoelectric ceramic composition according to claim 13, wherein, in a crystal structure analysis using X-ray diffraction, the second secondary phase containing Mn and Ni has a peak in a range of 2θ=41° to 44°.

15. The piezoelectric ceramic composition according to claim 13, wherein, in a crystal structure analysis using X-ray diffraction, the main phase has a maximum peak intensity I₀, and the second secondary phase containing Mn and Ni has a maximum peak intensity I₂ in a range of 2θ=41° to 44°, and a maximum peak intensity ratio represented by I₂/I₀ is less than 0.04.

16. A method of manufacturing a piezoelectric element, the method comprising:
mixing and calcining a K compound containing K, a Na compound containing Na, and a Nb compound containing Nb to prepare a calcined product;
preparing a ceramic green sheet containing a Mn compound containing Mn and the calcined product; and
firing the ceramic green sheet in a reducing atmosphere.

17. The method of manufacturing a piezoelectric element according to claim 16, the method further comprising forming a conductive layer on the ceramic green sheet using a conductive paste containing Ni as a main component before the firing of the ceramic green sheet.

18. The method of manufacturing a piezoelectric element according to claim 16, the method further comprising laminating the ceramic green sheet on which the conductive layer has been formed to prepare a ceramic laminate before the firing of the ceramic green sheet.

19. A method of manufacturing a piezoelectric ceramic composition, the method comprising:
mixing and calcining a K compound containing K, a Na compound containing Na, and a Nb compound containing Nb to prepare a calcined product;
preparing a molded body containing a Mn compound containing Mn and the calcined product; and
firing the molded body in a reducing atmosphere.
